(19) United States
(12) Patent Application Publication
(10) Pub. No.: US 2011/0297436 A1
(43) Pub. Date: Dec. 8, 2011

(54) NET-LIKE METAL FINE PARTICLE MULTILAYER FILM AND METHOD FOR PRODUCING SAME

(75) Inventors: Junpei Ohashi, Otsu-shi (JP); Junji Michizoe, Otsu-shi (JP); Yasushi Takada, Otsu-shi (JP)

(73) Assignee: TORAY INDUSTRIES, INC., Tokyo (JP)

(21) Appl. No.: 13/201,704

(22) PCT Filed: Feb. 19, 2010
(86) PCT No.: PCT/JP2010/052505

§ 371 Date: Aug. 16, 2011

(30) Foreign Application Priority Data
Mar. 2, 2009 (JP) 2009-047614

(51) Int. Cl. H05K 9/00; B05D 5/06; B32B 3/10; B32B 15/02; B32B 5/16

(52) U.S. Cl. 174/389; 428/208; 427/162

(57) ABSTRACT

A network-like fine metal particle multilayer film has a network-like fine metal particle layer at least on one surface of a film substrate, which has an average total light transmittance of 70% or more, a total light transmittance variation of 5% or less, and a length of 2 m or more. The film is a long network-like metal fine particle multilayer film having high transparency, being suppressed in the occurrence of moiré and having small variations in the total light transmittance.

### RELATED APPLICATIONS

This is a §371 of International Application No. PCT/JP2010/052505, with an international filing date of Feb. 19, 2010 (WO 2010/101028 A1, published Sep. 10, 2010), which is based on Japanese Patent Application No. 2009-047614, filed Mar. 2, 2009, the subject matter of which is incorporated by reference.

### TECHNICAL FIELD

This disclosure relates to a long network-like fine metal particle multilayer film excellent in transparency and moiré resistance and small in total light transmittance variation and also to a method for producing the same.

### BACKGROUND

Conductive substrates are used in various apparatuses as circuit materials, and used as electromagnetic wave shielding substrates and for solar cells.

Electromagnetic wave shielding substrates are used for the purpose of shielding a variety of electromagnetic waves radiated from electromagnetic apparatuses such as household electric appliances, cell phones, personal computers and television sets. Especially among household digital electric appliances, strong electromagnetic waves are radiated from flat panel displays such as plasma display panels and liquid crystal television sets and are feared to affect the human bodies. These displays present images that are observed for long periods of time at near distances from the screens thereof and therefore require electromagnetic wave shielding substrates capable of shielding these electromagnetic waves.

In general, as the electromagnetic wave shielding substrates used in display panels, transparent conductive substrates are used. As the methods for producing the conductive substrates for presently used electromagnetic shielding substrates, various methods are employed. For example, each of JP 1999-170420 A and JP 2000-196286 A describes a method for producing a conductive substrate provided with a patterned conductive layer, in which a highly transparent conductive film is prepared by printing a lattice pattern or a network-like pattern as the conductive layer.

However, the aforementioned approaches have the following problems.

The method for forming a conductive layer by screen printing described in JP '420 is an excellent method for obtaining a transparent film having a pattern small in total light transmittance variation. However, because of screen printing, this method basically allows sheet-by-sheet production only and cannot be used to produce a long sheet. Therefore, a 2 m or longer sheet cannot be obtained. Further, this substrate has a problem of causing moiré since the lattice-like conductive layer has a regular structure.

In the above explanation, moiré refers to “the stripes formed when the patterns having points or lines regularly geometrically distributed therein are superimposed on each other.” On a plasma display, a pattern of streaks occurs on the screen. In the case where the electromagnetic shielding substrate provided on the front surface of a display is provided with a regular pattern such as a lattice, the interaction with the regular lattice-like barrier ribs partitioning the respective pixels of RGB of the rear substrate of the display causes moiré. Further, in the case where an electromagnetic shielding substrate is provided with a regular pattern such as a lattice, if the line width of the lattice is larger, moiré is more likely to occur.

In the method described in JP '286, a conductive layer is formed by offset printing. This method is also excellent for obtaining a transparent film with a pattern small in total light transmittance variation. However, this method also allows sheet-by-sheet production only and cannot be used to produce a long sheet. Therefore, a 2 m or longer sheet cannot be obtained.

It could therefore be helpful to provide a long network-like fine metal particle multilayer film highly transparent, unlikely to cause moiré and small in total light transmittance variation. It could also be helpful to provide a suitable method for producing such a network-like fine metal particle multilayer film.

### SUMMARY

We thus provide as follows:
1) A network-like fine metal particle multiplayer film having a network-like fine metal particle layer at least on one surface of a film substrate, which has an average total light transmittance of 70% or more, a total light transmittance variation of 5% or less, and a length of 2 m or more.
2) A method for producing a network-like fine metal particle multilayer film, comprising the step of coating at least one surface of a film substrate with a fine metal particle dispersion, to form a network-like fine metal particle layer on the film substrate by a die coating method using a die in which a manifold has a volume of 0.01 cc to 5.0 cc per 10 mm die coating width.

We provide a long network-like fine metal particle multilayer film highly transparent, unlikely to cause moiré, and suppressed in the variation of transparency. The network-like fine metal particle multilayer film can be suitably used for flat panel displays such as plasma display panels and liquid crystal television sets.

Further, the production method allows the network-like fine metal particle multilayer film to be obtained continuously at high productivity by applying a fine metal particle dispersion under specific conditions without causing such defects as streaks and flaws on the coating layer.

### BRIEF DESCRIPTION OF THE DRAWINGS

FIG. 1 is a plan view showing an example of the network-like structure of the network-like fine metal particle multilayer film.

FIG. 2 is a schematic drawing typically showing the method for measuring the air stream direction on a film.

FIG. 3 is a schematic drawing typically showing the method of measuring the air velocity on a film.

### MEANING OF SYMBOLS

1 . . . network-like fine metal particle multilayer film
2 . . . rod
3 . . . yarn
4 . . . air stream angle
5 . . . probe
6 . . . measuring hole
7 . . . anemometer

### DETAILED DESCRIPTION

This disclosure relates to a film solving the aforementioned problems, i.e., a long network-like fine metal particle multilayer film highly transparent, minimized in the occurrence of moiré, and suppressed in the variation of transparency, and free from such defects as streaks and flaws on the coating layer. More specifically, our film is a network-like fine metal particle multiplayer film having a network-like fine metal particle layer at least on one surface of a film substrate, which has an average total light transmittance of 70% or more, a total light transmittance variation of 5% or less, and a length of 2 m or more.

The network-like fine metal particle multiplayer film has a fine metal particle layer at least on one surface of the film. The network-like fine metal particle multilayer film may also have a fine metal particle layer formed on each of both the surfaces of the film, but considering transparency, a network-like fine metal particle multilayer film having a fine metal particle layer on one surface of the film is preferred to that having a fine metal particle layer on each of both the surfaces of the film.

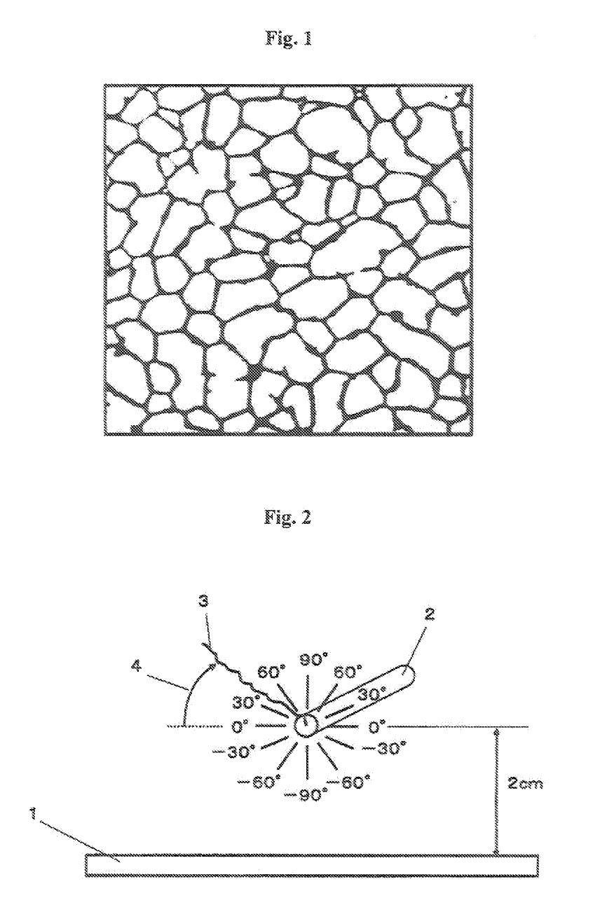

The network-like fine metal particle multilayer film has a fine metal particle layer like a network. In this description, a structure like a network means a structure in which multiple points are connected with each other by multiple line segments and FIG. 1 shows the network-like structure of the fine metal particle layer. That is, the network-like structure means a structure in which multiple line segments composed of fine metal particles and various additives and the like described later are connected with each other at multiple points. Meanwhile, the network-like fine metal particle layer of FIG. 1 shows an irregular network-like structure explained below.

It is preferred that the network-like structure of the fine metal particle layer is irregular. The reason is that in the case where the network-like fine metal particle multilayer film is used as stuck to a plasma display, if the network-like structure is irregular, moiré cannot occur.

The irregular network-like structure consists of line portions and the other void portions of a network, and the void portions are observed as those of different forms and sizes, that is, are in an irregular state. Further, the line portions of the network are often not straight and have different line thicknesses. An example of the irregular network-like structure is shown in FIG. 1, but the irregular network-like structure is not limited to this example.

The network-like fine metal particle multilayer film has a total light transmittance of 70% or more as a mean value. More preferred is 75% or more, and further more preferred is 77% or more. If the mean value of the total light transmittance is smaller than 70%, the network-like fine metal particle multilayer film may have a problem in view of transparency as the case may be. Further, it is more preferred that the minimum value of the total light transmittance is 70% or more. It is preferred that the minimum value of the total light transmittance is 70% or more, since there is no locally insufficiently transparent portion.

It is preferred that the mean value of the total light transmittance is higher, and the upper limit is not especially limited. However, considering the light reflection from the film surface, it is considered difficult to keep the mean value of the total light transmittance of the network-like fine metal particle multilayer film higher than 92%. Therefore, a total light transmittance of 92% as a mean value is considered to be the physical limit (upper limit) of the total light transmittance of the network-like fine metal particle multilayer film.

Further, the variation of the total light transmittance of the network-like fine metal particle multilayer film is 5% or less. Preferred is 3% or less, and further more preferred is 2% or less. In this description, the variation of the total light transmittance refers to the difference (absolute value) between the mean value and the maximum value of the total light transmittance or the difference (absolute value) between the mean value and the minimum value, whichever may be larger. Particularly, for example, if the mean value of the total light transmittance is 80%, the maximum value is 81% and the minimum value is 78%, then the difference (absolute value) between the mean value and the maximum value is 1% and the difference (absolute value) between the mean value and the minimum value is 2%. Therefore, the variation of the total light transmittance is 2%. In the case where the variation of the total light transmittance is larger than 5%, when the multilayer film is applied to a flat panel display such as a plasma display panel or liquid crystal television set, a problem of unevenness may occur in the display as the case may be.

Furthermore, it is preferred that the variation of the total light transmittance is smaller, and the lower limit is not especially limited. However, since the network-like fine metal particle multilayer film has a network-like fine metal particle layer or has an irregular network-like fine metal particle layer in a preferred mode, it is mechanically or physically difficult to perfectly eliminate the variation. Accordingly, it is considered difficult to keep the variation of the total light transmittance at less than 0.1%, and the lower limit is considered to be 0.1%. The total light transmittance is measured by the method described in “Examples” described later.

The fine metal particles used in the fine metal particle layer are not especially limited if they are fine particles composed of a metal. Examples of the metal include platinum, gold, silver, copper, nickel, palladium, rhodium, ruthenium, bismuth, cobalt, iron, aluminum, zinc, tin and the like. Any one of the metals may be used alone or two or more of them can also be used in combination.

The method for preparing fine metal particles can be, for example, a chemical method of reducing metal ions in a liquid layer, to obtain metal atoms and growing them to nanoparticles via atom clusters, or a method of evaporating a bulk metal in an inert gas, to form fine metal particles, and arresting the fine metal particles by a cold trap, or a physical method of vapor-depositing a metal on a thin polymer film, to form a thin metal film, and heating the thin metal film, to destroy it, for dispersing nanoparticles of the metal into the polymer in a solid phase or the like.

The fine metal particle layer is composed of fine metal particles as described above, and can contain various other additives, for example, inorganic and organic ingredients such as a dispersing agent, surfactant, protective resin, antioxidant, thermal stabilizer, anti-weathering stabilizer, ultraviolet light absorber, pigment, dye, organic or inorganic fine particles, filler and antistatic agent, in addition to the fine metal particles.

The network-like fine metal particle multilayer film is as long as 2 m or more. In the case where the network-like fine metal particle multilayer film is applied to a flat panel display such as a plasma display panel or liquid crystal television set, at least 2 m or more is required as the length considering post-processing or the like. That is, if the network-like fine metal particle multilayer film has a length of 2 m or more, it can be suitably used for a flat panel display. Meanwhile, in the case where the length is 2 m or more, in view of the transport of the film or the like, usually the network-like fine metal particle multilayer film is wound around a core, to be handled as a film roll. If the length of the network-like fine metal particle multilayer film is 2 m or more, the upper limit of the length is not especially limited. However, a thermoplastic resin film suitable as a film substrate described later may also be handled with a length of approx. 3,000 m at the longest. Therefore, it can be considered that the network-like fine metal particle multilayer film is handled with a length of approx. 3,000 m.

In the network-like fine metal particle multilayer film, to make the fine metal particle layer network-like, especially irregularly network-like, a method of using a fine metal particle dispersion can be employed for producing the network-like fine metal particle multilayer film. In the case where a fine metal particle dispersion is used to form a network-like structure, for example, a coating method of using a dispersion containing fine metal particles and particles of an organic ingredient such as a dispersing agent as solid particles (metal colloid dispersion) can be suitably used. As the solvent of the metal colloid dispersion, water or any of various organic solvents can be used.

When the network-like fine metal particle multilayer film is produced, a self-organizing fine metal particle dispersion can be preferably used as the fine metal particle dispersion. In this description, “a self-organizing fine metal particle dispersion” means a dispersion which naturally forms a network-like structure on a substrate if it is allowed to stand as coating on the entire surface of the substrate. As such a fine metal particle dispersion, for example, CE103-7 produced by Cima NanoTech can be used.

The network-like fine metal particle multilayer film can be produced by coating at least one surface of a film with the aforementioned fine metal particle dispersion. In the step of coating a film with the fine metal particle dispersion, it is preferred to use a coating method in which the coating device does not contact the film. Above all, it is preferred to use a die coating method.

In the case where a contact coating method in which the coating device contacts the film is used, a problem such that the film is flawed at the contacted portion or has streaks formed at the contacted portion when the film is coated with the fine metal particle dispersion occurs.

On the other hand, the coating method in which the coating device does not contact the film can be an applicator method, comma coating method, dipping method or the like, in addition to the die coating method. However, in the other coating methods than the die coating method, it is necessary to keep the fine metal particle dispersion collected in a liquid pan at the time of coating, and the fine metal particle dispersion may be coagulated in the liquid pan as the case may be. Further, since the liquid pan is used in an open system, the organic solvent that may be used in the fine metal particle dispersion volatilizes to change the concentration as the case may be. If the concentration change is caused by volatilization, the variation of the total light transmittance of the obtained network-like fine metal particle multilayer film may become large as the case may be. The die coating method does not require the collection of the fine metal particle dispersion in the liquid pan, and is performed in a closed system. Therefore, the concentration change caused by volatilization little occurs. That is, to decrease the variation of the total light transmittance of the fine metal particle multilayer film, it is preferred to use a die coating method in which the coating device does not contact the film, for coating the film with the fine metal particle dispersion.

As the method for producing the network-like fine metal particle multilayer film, it is preferred to use a die coating method and to keep the volume of the manifold in the die in a range from 0.01 cc to 5.0 cc per 10 mm die coating width. It is preferred to keep the volume of the manifold in this range, since a network-like fine metal particle multilayer film with a high total light transmittance and a small total light transmittance variation can be obtained. The form of the manifold is not especially limited. It is more preferred that the volume of the manifold in the die is 0.05 cc to 3.0 cc, and an especially preferred range is 0.1 cc to 0.5 cc. If the volume of the manifold is larger than 5.0 cc per 10 mm die coating width, the fine metal particle dispersion may stay in the manifold, to cause such a problem that the dispersion is coagulated as the case may be. On the contrary, if the volume is smaller than 0.01 cc, the amount of the fine metal particle dispersion staying in the manifold is so small that the dispersion cannot be stably supplied to the film, to cause uneven coating.

In the case where the network-like fine metal particle multilayer film is produced by a die coating method, it is preferred that the equivalent cross sectional area of the manifold in the die is 0.45 mm² to 150 mm². If the equivalent cross sectional area of the manifold is kept in this range, the dispersion can be stably supplied into the manifold, and as a result a network-like fine metal particle multilayer film with a high total light transmittance and a small total light transmittance variation can be obtained. It is more preferred that the equivalent cross sectional area of the manifold in the die is 0.45 mm² to 100 mm². A further more preferred range is 1 mm² to 50 mm², and an especially preferred range is 4 mm² to 20 mm². If the equivalent cross sectional area of the manifold in the die is larger than 150 mm², the dispersion may stay in the manifold when the dispersion has been supplied into the manifold, and the dispersion may be coagulated as the case may be. If the equivalent cross sectional area is smaller than 0.45 mm², the dispersion staying in the manifold may be narrow, and it may occur as the case may be that the dispersion cannot be stably supplied to the film and that the coagulation of the dispersion by shearing is caused.

In this description, the equivalent cross sectional area of the manifold refers to the cross sectional area of a circle through which a fluid is as likely to flow as the fluid that flows through the cross section of the manifold. If the equivalent cross sectional area of the manifold is large, the fluid is likely to flow, and on the contrary, if the equivalent cross sectional area of the manifold is small, the fluid is less likely to flow. The equivalent sectional area of the manifold can be obtained from the following formulae:

dₙ=4×s/l

Sₙ=(dₙ/2)²π

where

Sₙ: Equivalent cross sectional area of the manifold (mm²)

dₙ: Equivalent diameter of the manifold (mm)

s: Cross sectional area of the manifold (mm²)

l: Circumferential length of the cross section of the manifold (mm).

Even in the case where the cross sectional area of the manifold remains constant, if the circumferential length of the section of the manifold is long, that is, if the form of the cross section is flat, the fluid is less likely to flow. In this case, the equivalent cross sectional area of the manifold is small. On the contrary, if the circumferential length of the cross section of the manifold is short, that is, if the form of the cross section becomes close to a complete circle, the fluid is more likely to flow. In this case, the equivalent cross sectional area of the manifold is large. That is, the equivalent cross sectional area of a manifold is an indicator of fluid flowability for comparing manifolds equal in cross sectional area but different in form.

In the case where the network-like fine metal particle multilayer film is produced by a die coating method, it is preferred to exhaust the fine metal particle dispersion from the manifold to other than the film substrate surface, separately from coating the film substrate surface with the fine metal particle dispersion. More particularly it is preferred to establish openings for exhausting the fine metal particle dispersion from the manifold to other than the film substrate surface (hereinafter referred to as “the exhaust openings of the manifold”) separately from the openings for supplying the dispersion from the die to the film substrate (hereinafter referred to as “the delivery openings of the die”). If the fine metal particle dispersion is exhausted not only from the delivery openings of the die but also from the exhaust openings of the manifold, a network-like fine metal particle multilayer film with a higher total light transmittance and a smaller total light transmittance variation can be obtained. It is preferred that the amount exhausted from the exhaust openings of the manifold is 10 vol % or more with the coating amount supplied from the delivery openings of the die to the film substrate as 100 vol %. More preferred is 20 vol % or more, and especially preferred is 50 vol % or more. If the amount exhausted from the exhaust openings of the manifold is smaller than 10 vol % with the coating amount supplied from the delivery openings of the die as 100 vol %, the fine metal particle dispersion stays in the manifold in the die and may be coagulated as the case may be.

The upper limit of the amount exhausted from the exhaust openings of the manifold is not especially limited, since the stay and coagulation of the dispersion in the manifold in the die decreases if the exhaust amount is larger. However, considering the coating stability by the coating amount supplied from the delivery openings of the die, if the amount exhausted from the exhaust openings of the manifold is 100 vol % or less with the coating amount supplied from the delivery openings of the die as 100 vol %, stable coating is considered to be assured.

After the film is coated with the fine metal particle dispersion, it is preferred that the air on the coating surface is made to flow in a direction within a range of 0±45 degrees with the direction parallel to the film surface as 0 degrees. The direction in which air flows, i.e., the air stream angle is measured as described below. In the step of coating the film substrate with the fine metal particle dispersion, to form a fine metal particle layer, a rod with a 2 cm yarn attached at the tip thereof is placed in parallel to the film at a place of 2 cm above the coating surface at the center of the film in the transverse direction. If the yarn attached at the tip of the rod streams in parallel to the film surface, the air stream angle is 0 degrees. If the yarn streams vertically upward, the air stream angle is 90 degrees. If the yarn streams vertically downward, the air stream angle is −90 degrees (see FIG. 2). It is preferred that the air stream angle is in a range of 0±45 degrees, and a more preferred range is 0±30 degrees. A further more preferred range is 0±15 degrees, and an especially preferred range is 0±5 degrees. If the air stream angle is outside the range of 0±45 degrees, the structure of the fine metal particle layer connected like a network may be disconnected as the case may be when the air stream velocity is made high. For this reason, when the network-like fine metal particle multilayer film is used as a conductive film, a problem in view of conductivity may occur as the case may be. If the air stream angle is kept in the range of 0 degrees±45 degrees and the air stream velocity is controlled as described later, then a network-like fine metal particle layer can be formed on the film substrate in a very short time period of 30 seconds or less. If the time period for forming the network-like fine metal particle layer becomes longer, the production equipment such as the drying device for causing the air stream to flow in a continuous process becomes very long. Consequently, any measure for slowing the speed of the production process is necessary. In the case where the network-like fine metal particle layer can be formed in a very short time period of 30 seconds or less, when our method is applied to a continuous process, ordinary production equipment can be used. Further, since it is not necessary to slow the speed of the production process, a network-like fine metal particle multilayer film with a length of 2 m or more can be obtained without raising the cost.

Further, in the case where the network-like fine metal particle multilayer film is applied to a process of continuous coating, it is preferred that the direction of the air stream is parallel to the machine direction of the film. If the air stream direction is parallel to the machine direction, the air stream can flow in the same direction as the flow of the film or in the direction reverse to the flow of the film without any problem. If the air stream flows in the transverse direction of the film, the coating layer may become uneven as the case may be when the network-like fine metal particle multilayer film is obtained.

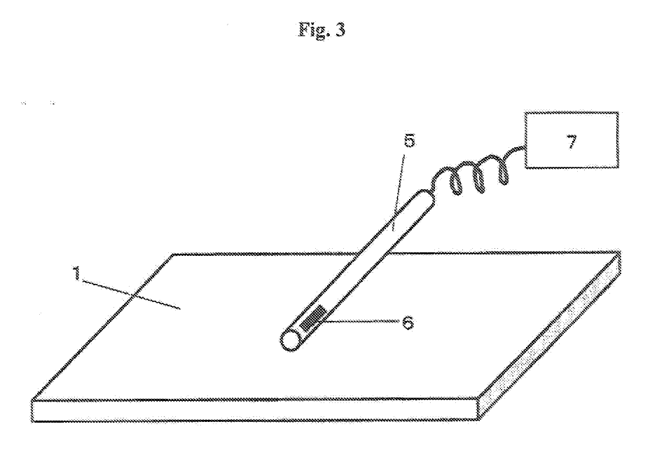

It is preferred that the velocity of the air stream in a direction within a range of 0±45 degrees is 1 msec to 10 msec. The velocity of the air stream is measured using an anemometer as described below. In the step of coating the film substrate with a fine metal particle dispersion, to form a fine metal particle layer, the anemometer is placed in such a manner that the measuring face of the probe may come at a place of 1 cm above the coating surface at the center of the film in the transverse direction. The angle of the probe is adjusted to ensure that the velocity of only the air stream of the angle measured by the abovementioned air stream angle measuring method may be measured. Further, the air velocity is measured for 30 seconds in a stationary state (see FIG. 3). The maximum value among the values measured for 30 seconds is employed as the velocity of the air stream.

It is preferred that the velocity of the air stream is 1 msec to 10 msec. A more preferred range is 2 msec to 8 msec, and a further more preferred range is 3 msec to 6 msec. If the velocity of the air stream is higher than 10 msec, the structure connected like a network may be disconnected as the case may be irrespective of the air stream angle. For this reason, in the case where the network-like fine metal particle multilayer film is used as a conductive film, a problem in view of conductivity may occur as the case may be. Further, if the velocity is lower than 1 msec, a network-like fine metal particle film can be obtained, but considering the application to a continuous process, it takes such a long time to form a network-like fine metal particle layer that a problem of productivity such as cost hike may occur.

The air stream can be generated by exhausting the air on the film or by supplying air onto the film. The air exhaust or air supply method is not especially limited. For example, as an air exhaust method, an exhaust fan, draft or the like can be used for exhausting air. Further, as an air supply method, a cooler, dryer or the like can be used to supply air. It is preferred to exhaust air for generating an air stream since the air stream can flow in a constant direction without disturbance on the film. An air supply method presses air into stationary air from an air supply device, and the air stream direction is inevitably likely to be disturbed. On the other hand, an air exhaust method is to pull stationary air toward the exhaust device side, and therefore it is easy to keep the direction of the air stream constant. It is preferred that the air stream on the film flows in a constant direction without disturbance for such reasons that the coating layer can be kept even and that the variation of the total light transmittance can be kept small.

After the film substrate is coated with the fine metal particle dispersion, it is preferred that the time period during which the air on the coating surface is kept flowing in a direction within a range of 0±45 degrees is 30 seconds or less. A more preferred time period is 25 seconds or less, and a further more preferred time period is 20 seconds or less. In the case where the time period during which air flows is longer than 30 seconds, if our method is applied to a continuous process, it is necessary to elongate the production equipment such as a drying device, or to slow the speed of the production process, thereby causing the problem of productivity such as cost hike. Further, though it is preferred that the time period during which air is kept flowing is shorter, the shortest time period is necessary to render the coating layer like a network. Therefore, it is realistically difficult to keep the time period at less than 5 seconds. A period of 5 seconds is considered to be the lower limit. The time period during which air is kept flowing can be adjusted by adjusting the time period during which the film passes through the device in which air is kept flowing, or by adjusting the time period during which an air exhaust or supply device for exhausting the air on a stationary film or supplying air onto the stationary film is operated.

In view of the above, a method of coating a film substrate with a fine metal particle dispersion and subsequently causing the air on the coating surface to flow in a direction within a range of 0±45 degrees at an air velocity of 1 msec to 10 msec for 30 seconds or less is a suitable method for rendering the fine metal particle layer like a network.

The temperature above the film during the period from the start of the coating of a film substrate with a fine metal particle dispersion to the completion of the coating and the temperature above the film while air is made to flow in a direction within a range of 0±45 degrees after the coating with the fine metal particle dispersion are not especially limited, and can be, as appropriate, selected depending on the solvent used in the fine metal particle dispersion. However, it is preferred to control the temperature above the film, for satisfying a condition of 10 to 50° C. A more preferred range is 15 to 40° C., and an especially preferred range is 15 to 30° C. If the temperature above the film is lower than 10° C. or higher than 50° C., the total light transmittance declines, and a problem may occur in view of the transparency of the network-like fine metal particle multilayer film as the case may be. Further, the structure connected like a network may be disconnected as the case may be. For this reason, in the case where the network-like fine metal particle multilayer film is used as a conductive substrate, a problem in view of conductivity may occur as the case may be.

The temperature above the film is measured as described below. In the step of coating a film substrate with a fine metal particle dispersion, to form a network-like fine metal particle layer, a thermometer is used to measure the temperature at 1 cm above the film surface at the center of the film in the transverse direction.

Considering the control of the temperature above the film within the above-mentioned range, it is preferred that the temperature of the air made to flow in a direction within a range of 0±45 degrees after the coating of the fine metal particle dispersion is 10 to 50° C. A more preferred range is 15 to 40° C., and an especially preferred range is 15 to 30° C.

It is preferred to control the humidity above the film in an atmosphere satisfying a condition of 1 to 85% RH during the period from the start of the coating of a film substrate with a fine metal particle dispersion to the completion of the coating and, further, while air is made to flow in a direction within a range of 0±45 degrees after the coating with the fine metal particle dispersion. A more preferred range is 10 to 70% RH, and a further more preferred range is 20 to 60% RH. An especially preferred range is 30 to 50% RH. If the humidity above the film is lower than 1% RH, the total light transmittance declines, and a problem may occur in view of the transparency of the network-like fine metal particle multilayer film as the case may be. If the humidity above the film is higher than 85% RH, the structure connected like a network may be disconnected as the case may be. For this reason, in the case where the network-like fine metal particle multilayer film is used as a conductive substrate, a problem in view of conductivity may occur as the case may be.

The humidity above the film is measured as described below. In the step of coating a film substrate with a fine metal particle dispersion, to form a network-like fine metal particle layer, a hygrometer is used to measure the humidity at 1 cm above the film surface at the center of the film in the transverse direction.

Considering the control of the humidity above the film within the above-mentioned range, it is preferred that the humidity of the air made to flow in a direction within a range of 0±45 degrees after the coating with the fine metal particle dispersion is 1 to 85% RH. A more preferred range is 10 to 80% RH, and a further more preferred range is 20 to 60% RH. An especially preferred range is 30 to 50% RH.

In the case where a fine metal particle dispersion capable of self-organizing a network-like form is used as the fine metal particle dispersion, it is preferred that the temperature and humidity above the film are maintained at specific conditions as described above during the period from the start of the coating with the fine metal particle dispersion till the fine metal particle dispersion self-organizes a network-like form.

Further, in the network-like fine metal particle multilayer film obtained by the abovementioned production method, the fine metal particle layer can be further heat-treated to enhance conductivity. It is preferred that the temperature of the heat treatment is 100° C. to lower than 200° C. A more preferred range is 130° C. to 180° C., and a further more preferred range is 140° C. to 160° C. If the heat treatment is performed at a high temperature of 200° C. or higher for a long time period, a problem such as film deformation may occur as the case may be. In the case where the heat treatment temperature is lower than 100° C., if the network-like fine metal particle multilayer film is used as a transparent conductive film, a problem in view of conductivity may occur as the case may be.

It is preferred that the time period of the heat treatment is 10 seconds to 3 minutes. A more preferred range is 20 seconds to 2 minutes, and a further more preferred range is 30 seconds to 2 minutes. In the case where the heat treatment is performed for a time period of shorter than 10 seconds, if the network-like fine metal particle multilayer film is used as a conductive film, a problem in view of conductivity may occur as the case may be. In the case where the heat treatment is performed for a time period of longer than 3 minutes, if the application to a continuous process is taken into consideration, a long time period is necessary for the heat treatment step, and a problem in view of productivity such as cost hike may occur.

If the fine metal particle layer is further treated with an acid and an organic solvent in succession to the abovementioned heat treatment, the conductivity can be further enhanced.

The method of treating with an acid allows the conductivity of the fine metal particles to be enhanced under mild treatment conditions, and therefore even in the case where a material poor in heat resistance and light resistance such as a thermoplastic resin is used as the film substrate, acid treatment can be performed. Further, the method is preferred also in view of productivity since any complicated equipment or process is not required.

The acid used for the acid treatment is not especially limited and can be selected from various organic acids and inorganic acids. The organic acids include acetic acid, oxalic acid, propionic acid, lactic acid, benzenesulfonic acid and the like. The inorganic acids include hydrochloric acid, sulfuric acid, nitric acid, phosphoric acid and the like. Any of these acids can be a strong acid or weak acid. Preferred are acetic acid, hydrochloric acid, sulfuric acid and aqueous solutions thereof. More preferred are hydrochloric acid, sulfuric acid and aqueous solutions thereof.

The particular method of treating with an acid is not especially limited. For example, a film having a fine metal particle layer laminated thereon can be immersed in an acid or a solution of the acid, or the fine metal particle layer can be coated with an acid or a solution of the acid. As a further other method, the vapor of an acid or the vapor of a solution of the acid can be applied to a fine silver particle layer.

As for the stage when the fine metal particle layer is treated with an organic solvent, a method can be suitably used in which fine metal particles are laminated like a network on a film and then the network-like fine metal particle multilayer film is treated with the organic solvent, for such reasons the effect of enhancing the conductivity is excellent and that the efficiency in view of productivity is good. Further, before or after the treatment with an organic solvent, the film having a fine metal particle layer laminated thereon can also be printed or coated with another layer for lamination. Further, before or after the treatment with an organic solvent, the film having a fine metal particle layer laminated thereon can also be dried, heat-treated or treated by irradiation with ultraviolet light.

When the fine metal particle layer is treated with an organic solvent, room temperature is sufficient as the temperature of the treatment with the organic solvent. If the treatment is performed at a high temperature, the film may be whitened to impair transparency as the case may be. It is preferred that the treatment temperature is 40° C. or lower. More preferred is 30° C. or lower, and especially preferred is 25° C. or lower.

The method for treating the fine metal particle layer with an organic solvent is not especially limited. For example, a method of immersing the film having a fine metal particle layer laminated thereon into a solution of the organic solvent, or a method of coating the fine metal particle layer with the organic solvent or a method of applying the vapor of the organic solvent to the fine metal particle layer can be used. Among them, a method of immersing the film having a fine metal particle layer laminated thereon into the organic solvent or a method of coating the fine metal particle layer with the organic solvent is preferred since the effect of enhancing the conductivity is excellent.

Examples of the organic solvent include alcohols such as methyl alcohol, ethyl alcohol, isopropyl alcohol, n-butanol, isobutanol, 3-methoxy-3-methyl-1-butanol, 1,3-butanediol and 3-methyl-1,3-butanediol, ketones such as acetone, methyl ethyl ketone, methyl isobutyl ketone, cyclohexanone and cyclopentanone, esters such as ethyl acetate and butyl acetate, alkanes such as hexane, heptane, decane and cyclohexane, bipolar aprotic solvents such as N-methyl-2-pyrrolidone, dimethylformamide, dimethylacetamide and dimethyl sulfoxide, toluene, xylene, aniline, ethylene glycol butyl ether, ethylene glycol ethyl ether, ethylene glycol methyl ether, chloroform or the like, and mixed solvents thereof. Among them, ketones, esters and toluene are preferred since the effect of enhancing the conductivity is excellent. Especially preferred are ketones.

Further, if the fine metal particle layer of the network-like fine metal particle multilayer film is treated with an organic solvent after it has been heat-treated but before it is treated with an acid, the conductivity of the network-like fine metal particle multilayer film can be further enhanced.

As the conductivity of the network-like fine metal particle multilayer film, it is preferred that the mean value of the surface resistivity is 100 Ω/sq. (ohm/square) or less. More preferred is 70 Ω/sq. or less, and further more preferred is 50 Ω/sq. or less. Especially preferred is 30 Ω/sq. or less. It is preferred that the mean value of the surface resistivity is 100 Ω/sq. or less, for such reasons that when the network-like fine metal particle multilayer film used as a transparent conductive film is energized, heat generation is suppressed since the load due to resistance is small, and that the film can be used at a low voltage. Further, such a surface resistivity level is preferred since the electromagnetic wave shieldability is good in the case where the multilayer sheet is used as a transparent conductive film for an electromagnetic wave shielding substrate of a flat panel display such as a plasma display panel or liquid crystal television set. It is preferred that the surface resistivity of a conductive film is lower, but it is considered actually difficult to keep the surface resistivity at lower than 0.1 Ω/sq. Therefore, the lower limit of the mean value of the surface resistivity is considered to be 0.1 Ω/sq.

Furthermore, it is also more preferred that the maximum value of the surface resistivity is 100 Ω/sq. or less. It is preferred that the maximum value of the surface resistivity is 100 Ω/sq. or less, since there is no portion where the resistance load is locally high.

It is preferred that the variation of the surface resistivity of the network-like fine metal particle multilayer film is 30% or less. More preferred is 20% or less, and especially preferred is 15% or less. In this description, the variation of the surface resistivity is the difference (absolute value) between the mean value and the maximum value of the surface resistivity or the difference (absolute value) between the mean value and the minimum value, whichever may be larger. Particularly, for example, if the mean value of the surface resistivity is 30 Ω/sq., the maximum value is 36 Ω/sq. (the mean value+6 Ω/sq.) and the minimum value is 27 Ω/sq. (the mean value−3 Ω/sq.), then the rate of the difference (absolute value) between the mean value and the maximum value to the mean value is 20%, while the rate of the difference (absolute value) between the mean value and the minimum value to the mean value is 10%. Therefore, the variation of the surface resistivity is 20%. In the case where the variation of the surface resistivity is larger than 30%, if the network-like fine metal particle multilayer film is used as a transparent conductive film, the conductivity becomes uneven, and such a problem that the energization or signals become unstable may occur as the case may be. The specific resistivity is a value measured by the method described in the “Examples” described later.

Moreover, the variation of the surface resistivity can be suppressed by a die coating method in which the volume of the manifold in the die is kept in a range from 0.01 cc to 5 cc per 10 mm die coating width, or in which the amount of the fine metal particle dispersion exhausted from the exhaust openings of the manifold is kept at 10 vol % or more with the coating amount supplied from the delivery openings of the die to the film substrate as 100 vol %.

The film substrate is not especially limited. However, it is preferred that the film has a hydrophilically treated layer laminated on the surface thereof, since the fine metal particles can be easily laminated like a network. The hydrophilically treated layer is not especially limited, but a layer composed of a polyester, acryl-modified polyester, polyurethane, acrylic resin, methacrylate-based resin, polyamide, polyvinyl alcohol, a natural resin such as starch, cellulose derivative or gelatin, polyvinyl pyrrolidone, polyvinyl butyral, polyacrylamide, epoxy resin, melamine resin, urea resin, polythiophene, polypyrrole, polyacetylene, polyaniline, any of various silicone resins, modified silicone resins and the like can be used.

It is preferred that the film substrate is a thermoplastic resin film, since it is excellent in transparency, flexibility and processability. The thermoplastic resin film generally refers to a film capable of being molten or softened by heat, and is not especially limited. However, in view of mechanical properties, dimensional stability, transparency and the like, a polyester film, polypropylene film, polyamide film or the like are preferred. Further in view of mechanical strength and general purpose use or the like, a polyester film is especially preferred.

The network-like fine metal particle multilayer film may have any of various layers laminated in addition to the film substrate and the fine metal particle layer. For example, an undercoating layer for enhancing adhesion may be formed between the film substrate and the fine metal particle layer, or a protective layer may also be formed on the fine metal particle layer. Further, an adhesive layer, releasing layer, protective layer, adhesive tackifier layer, anti-weathering layer or the like can also be formed on one surface or each of both the surfaces of the film substrate. In the case where any of these various layers is formed between the film substrate and the fine metal particle layer, it is preferred that the surface wet tension of the layer to be coated with a fine metal particle dispersion on the film substrate is 45 mN/m to 73 mN/m.

The network-like fine metal particle multilayer film is highly transparent and unlikely to cause moiré, and in a preferred mode, it has high conductivity. Therefore, it can be used as an electromagnetic wave shielding film used for a flat panel display such as a plasma display panel or liquid crystal television set. Furthermore, it can be used for circuit materials, transparent heaters, solar cells, and various transparent conductive films.

### EXAMPLES

The network-like fine metal particle multilayer film is explained below more particularly in reference to examples, but this film is not limited thereto or thereby.

### Methods for Measuring Properties and Methods for Evaluating Effects

The methods for measuring the properties and the methods for evaluating the effects of the network-like fine metal particle multilayer films prepared in the respective Examples and Comparative Examples are as described below.

### (1) Observation of the Surface (Observation of Network-Like Form)

The surface of a network-like fine metal particle multilayer film is observed using a differential interference microscope (LEICA DMLM produced by Leica Microsystems) at a magnification of 100×, to observe the network-like form.

### (2) Surface Resistivity

The surface resistivity is obtained as described below. A network-like fine metal particle multilayer film is allowed to stand in an atmosphere of 23° C. temperature and 65% relative humidity for 24 hours. Then, in the same atmosphere, the surface resistivity is measured according to JIS K 7194 (1994). As the measuring instrument, Lowresta EP (MCP-T360) produced by Mitsubishi Chemical Corporation is used. The measuring instrument can measure 1×10⁶ Ω/sq. or less.

In a range of 2 m in the machine direction of a network-like fine metal particle multilayer film, the surface resistivity values are measured at the respective points of 10 cm intervals in the machine direction and 10 cm intervals in the transverse direction (direction perpendicular to the machine direction). The mean value of the surface resistivity values at all the measuring points is employed as the surface resistivity of the network-like fine metal particle multilayer film.

In the case where the length of the network-like fine metal particle multilayer film in the machine direction is more than 10 m, the surface resistivity values are measured in the same way in each range of 2 m in the machine direction of every 10 m in the machine direction, and the mean value of the surface resistivity values at all the measuring points is obtained to be employed as the surface resistivity of the network-like fine metal particle multilayer film. For example, in the case where the length of the network-like fine metal particle multilayer film is 30 m, the surface resistivity values are measured at the respective measuring points in the first 2 m range in the machine direction, in the second 2 m range in the machine direction starting from the 12 m portion apart from the first range by 10 m, and in the third 2 m range in the machine direction starting from the 24 m portion apart from the second range by 10 m, and the mean value of the surface resistivity values at all the measuring points is obtained.

If the mean value of the surface resistivity is 100 Ω/sq. or less, the conductivity is good.

### (3) Variation of Surface Resistivity

The variation of the surface resistivity is obtained as described below. The mean value, the maximum value and the minimum value are obtained from the surface resistivity values measured at all the measuring points in (2). The rate of the difference (absolute value) between the mean value and the maximum value to the mean value and the rate of the difference (absolute value) between the mean value and the minimum value to the mean value are obtained, and the larger value is employed as the variation of the surface resistivity.

If the variation of the surface resistivity is 30% or less, the variation is good.

### (4) Total Light Transmittance

The total light transmittance is obtained as described below. A network-like fine metal particle multilayer film is allowed to stand in an atmosphere of 23° C. temperature and 65% relative humidity for 2 hours. Subsequently, the total light transmittance is measured by a measuring instrument. As the measuring instrument, a full automatic direct-reading haze computer “HGM-2DP” produced by Suga Test Instruments Co., Ltd. is used. In the case of a multilayer film having a fine metal particle layer laminated on one surface only of the film, the film is installed in such a manner that light may fall on the side of the fine metal particle layer.

In a range of 2 m in the machine direction of a network-like fine metal particle multilayer film, the total light transmittance values are measured at the respective points of 10 cm intervals in the machine direction and 10 cm intervals in the transverse direction. The mean value of the total light transmittance values at all the measuring points is employed as the total light transmittance of the network-like fine metal particle multilayer film.

In the case where the length of the network-like fine metal particle multilayer film in the machine direction is more than 10 m, the total light transmittance values are measured in the same way in a range of 2 m in the machine direction of every 10 m in the machine direction, and the mean value of the total light transmittance values at all the measuring points is obtained to be employed as the total light transmittance of the network-like fine metal particle multilayer film. For example, in the case where the length of the network-like fine metal particle multilayer film is 30 m, the total light transmittance values are measured at the respective measuring points in the first 2 m range in the machine direction, in the second 2 m range in the machine direction starting from the 12 m portion apart from the first range by 10 m, and in the third 2 m range in the machine direction starting from the 24 m portion apart from the second range by 10 m, and the mean value of the total light transmittance values at all the measuring points is obtained.

If the mean value of the measured total light transmittance values is 70% or more, the transparency is good.

### (5) Variation of Total Light Transmittance

The variation of the total light transmittance is obtained as described below. The mean value, the maximum value and the minimum value are obtained from the total light transmittance values measured at all the measuring points in (4). The rate of the difference (absolute value) between the mean value and the maximum value to the mean value and the rate of the difference (absolute value) between the mean value and the minimum value to the mean value are obtained, and the larger value is employed as the variation of the total light transmittance.

If the variation of the total light transmittance is 5% or less, the variation is good.

(6) Moiré Phenomenon

The moiré is evaluated as described below. In front of the screen of the display on which an image is displayed, a network-like fine metal particle multilayer film is held in such a manner that the screen and the film may become almost parallel to each other. While the screen and the film are kept such that the screen and the film surface may be kept parallel to each other, the film is rotated 360°, to visually observe whether or not moiré phenomenon may occur during the rotation. In the case where a fine metal particle layer is laminated on one surface only of the film, the film should be held such that the side free from the fine metal particle layer laminated may face the display screen. As the display, plasma display VIERA TH-42PX50 produced by Matsushita Electric Industrial Co., Ltd. is used.

A film with which no moiré is observed is evaluated as “A” while a film with which moiré is observed even partially is evaluated as “B.” Evaluation “A” means that the film is good in view of moiré.

(7) Air Stream Angle at the Time when a Fine Metal Particle Layer is Laminated

The air stream angle is measured as described below. In the step of coating a film substrate with a fine metal particle dispersion, to form a fine metal particle layer, a rod with a yarn of 2 cm attached at the tip thereof is placed in parallel to the film at a place of 2 cm above the film surface at the center of the film in the transverse direction, for measurement. If the yarn attached at the tip of the rod streams in parallel to the film surface, the air stream angle is 0 degrees, and if the yarn streams vertically upward, the air stream angle is 90 degrees. If the yarn streams vertically downward, the air stream angle is −90 degrees. For measurement, a polyester-based multifilament with a thickness of 140 dtex is used as the yarn.

(8) Air Stream Velocity at the Time when a Fine Metal Particle Layer is Laminated

The air stream velocity is measured as described below. In the step of coating a film substrate with a fine metal particle dispersion, to form a network-like fine metal particle layer, an anemometer is placed such that the measuring face of the probe may be at a place of 1 cm above the film surface at the center of the film in the transverse direction. The angle of the probe is adjusted to measure the air velocity of only the air stream with the angle measured in (7). The air velocity is measured for 30 seconds in a stationary state (see FIG. 3). The maximum value of the values measured for 30 seconds is employed as the air stream velocity. As the anemometer, CLIMOMASTER (MODEL 6531) produced by Kanomax Japan, Inc. is used.

### (9) Surface Wet Tension

The surface wet tension of the film is measured as described below. Any of the films used in the respective Examples and Comparative Examples is allowed to stand in an atmosphere of 23° C. temperature and 50% relative humidity for 6 hours. Then, the surface wet tension is measured in the same atmosphere according to JIS K 6768 (1999).

At first, the film is placed on the base of a hand coater in such a manner that the surface to be measured may be turned upward. Several drops of a surface wet tension testing mixture solution are added onto the film surface and immediately a wiper bar capable of coating in a wet thickness of 12 μm is drawn for spreading.

To decide the surface wet tension, the liquid film of the testing mixture solution is observed 2 seconds layer in a bright place. If the state as coated is kept for 2 seconds or more without causing the liquid film to be broken, wetting prevails. In the case where wetting is kept for 2 seconds or more, a mixture solution with a higher surface wetting tension is used for similar evaluation. On the contrary, in the case where the liquid film is broken in less than 2 seconds, a mixture solution with a lower surface wet tension is used for similar evaluation. This operation is repeated to select the mixture solution that can wet the surface of the film for almost 2 seconds, to identify the surface wet tension of the film. The maximum surface wet tension by this measuring method is 73 mN/m. The surface wet tension is expressed in mN/m.

(10) Humidity Above a Film at the Time when a Fine Metal Particle Layer is Formed

The humidity above a film is measured as described below. In the step of coating a film substrate with a fine metal particle dispersion, to form a network-like fine metal particle layer, the humidity at 1 cm above the film surface is measured at the center of the film in the transverse direction. The humidity is measured for 15 seconds or more, and a stabilized value is employed. As the measuring instrument, CLIMOMASTER (MODEL 6531) is used.

(11) Temperature Above a Film at the Time when a Fine Metal Particle Layer is Formed

The temperature above a film is measured as described below. In the step of coating a film substrate with a fine metal particle dispersion, to form a network-like fine metal particle layer, the temperature at 1 cm above the film surface is measured at the center of the film in the transverse direction. The temperature is measured for 30 seconds or more, and a stabilized value is employed. As the measuring instrument, CLIMOMASTER (MODEL 6531) produced by Kanomax Japan, Inc. is used.

Our films and methods are explained below based on Examples.

### Fine Metal Particle Dispersion 1

As fine metal particle dispersion 1, CE103-7 produced by Cima NanoTech as a fine silver particle dispersion was used.

### Fine Metal Particle Dispersion 2

Monoethanolamine was added dropwise into an aqueous solution of silver nitrate, to obtain an aqueous solution of silver alkanolamine complex (aqueous solution 1). Separately from the solution, monoethanolamine was added to an aqueous solution with quinone dissolved therein as a reducing agent, to prepare another aqueous solution (aqueous solution 2). Then, the aqueous solution 1 and the aqueous solution 2 were simultaneously poured into a plastic container, to reduce the silver alkanolamine complex, for obtaining fine silver particles. The mixed solution was filtered, and the residue was washed with water and dried, to obtain fine silver particles. The fine silver particles were re-dissolved into water, to obtain a fine silver particle dispersion. The number average particle size of the fine silver particles was 1.4 μm.

### Example 1

A biaxially oriented polyethylene terephthalate film (Lumirror (registered trademark) U46, surface wet tension 47 mN/m, produced by Toray Industries, Inc.) was coated on one surface with a primer, as hydrophilic treatment. The surface wet tension of the hydrophilically treated film was 73 mN/m. In succession, the air on the substrate was exhausted using an exhaust fan, causing air with a temperature of 25° C. and a relative humidity of 45% to flow in the direction of 0 degrees in parallel to the substrate surface. Further, the air stream velocity was adjusted to 4 msec. The temperature above the film at this time was 25° C., and the humidity was 45% RH. Under the air stream the hydrophilically treated layer of the biaxially oriented polyethylene terephthalate film was coated with the fine metal particle dispersion 1 to have a wet thickness of 30 μm, using a die coating method. At this time, the exhaust amount from the exhaust openings of the manifold in the die was 24 vol % with the coating amount supplied from the die as 100 vol %. The volume of the manifold in the die was 0.2 cc per 10 mm die coating width, and the equivalent cross sectional area of the manifold in the die was 13 mm².

The applied fine silver particle dispersion (the fine metal particle dispersion 1) self-organized an irregular network-like form after completion of coating. Thus, a multilayer film having a fine silver particle layer formed like a network was obtained. The obtained multilayer film was in succession heat-treated in an oven of 150° C. for 1 minute, to obtain a network-like fine metal particle multilayer film. The length of the film was 100 m.

The obtained network-like fine metal particle multilayer film was like an irregular network. Within the range of the 100 m length, the mean value of the total light transmittance was 80%. The maximum value of the total light transmittance was 81%, and the minimum value was 78%. The variation of the total light transmittance was as good as 2%. The mean value of the surface resistivity was 30 Ω/sq. The maximum value of the surface resistivity was 36 Ω/sq., and the minimum value was 27 Ω/sq. The variation of the surface resistivity was as good as 20%. The moiré resistance was “A.”

### Example 2

A network-like fine metal particle multilayer film was obtained as described in Example 1, except that the length of the film was 2 m.

The obtained network-like fine metal particle multilayer film was like an irregular network. Within the range of the 2 m length, the mean value of the total light transmittance was 80%. The maximum value of the total light transmittance was 81%, and the minimum value was 79%. The variation of the total light transmittance was 1%. The variation of the total light transmittance was better than that of Example 1. Further, the mean value of the surface resistivity was 30 Ω/sq. The maximum value of the surface resistance was 33 Ω/sq., and the minimum value was 27 Ω/sq. The variation of the surface resistivity was 10%. The variation of the surface resistivity was better than that of Example 1. The moiré resistance was “A.”

### Example 3

A network-like fine metal particle multilayer film was obtained as described in Example 1, except that the length of the film was 2,000 m.

The obtained network-like fine metal particle multilayer film was like an irregular network. Within the range of the 2,000 length, the mean value of the total light transmittance was 80%. The maximum value of the total light transmittance was 81%, and the minimum value was 78%. The variation of the total light transmittance was 2%. Even though the network-like fine metal particle multilayer film has a length of 2,000 m longer than that of Example 1, the variation of the total light transmittance was as good as that of Example 1. The mean value of the surface resistance was 30 Ω/sq. The maximum value of the surface resistivity was 36 Ω/sq., and the minimum value was 27 Ω/sq. The variation of the surface resistivity was 20%. The variation of the surface resistivity was as good as that of Example 1. The moiré resistance was “A.”

### Example 4

A network-like fine metal particle multilayer film was obtained as described in Example 1, except that the volume of the manifold in the die was 0.5 cc per 10 mm die coating width, and that the equivalent cross sectional area of the manifold in the die was 30 mm². The volume of the manifold and the equivalent cross sectional area of the manifold threatened to cause a larger amount of the fine metal particle dispersion to stay in the manifold than those of the die of Example 1.

The obtained network-like fine metal particle multilayer film was like an irregular network. Within the range of the 100 m length, the mean value of the total light transmittance was 79%. The maximum value of the total light transmittance was 81%, and the minimum value was 77%. The variation of the total light transmittance was as good as 2%. The total light transmittance and the variation of the total light transmittance were like those of Example 1, but the minimum value of the total light transmittance was inferior to that of Example 1. The mean value of the surface resistivity was 30 Ω/sq. The maximum value of the surface resistivity was 36 Ω/sq., and the minimum value was 27 Ω/sq. The variation of the surface resistivity was as good as 20%. The moiré resistance was “A.”

### Example 5

A network-like fine metal particle multilayer film was obtained as described in Example 1, except that the volume of the manifold in the die was 1.0 cc per 10 mm die coating width, and that the equivalent cross sectional area of the manifold in the die was 60 mm². The volume of the manifold and the equivalent cross sectional area of the manifold threatened to cause a larger amount of the fine metal particle dispersion to stay in the manifold than those of the die of Example 4.

The obtained network-like fine metal particle multilayer film was like an irregular network. Within the range of the 100 m length, the mean value of the total light transmittance was 79%. The maximum value of the total light transmittance was 81%, and the minimum value was 76%. The variation of the total light transmittance was as good as 3%. However, the mean value of the total light transmittance and the variation of the total light transmittance were inferior to those of Example 1. The mean value of the surface resistivity was 30 Ω/sq. The maximum value of the surface resistivity was 37 Ω/sq., and the minimum value was 27 Ω/sq. The variation of the surface resistivity was as good as 23%. However, the variation of the surface resistivity was inferior to that of Example 1. The moiré resistance was “A.”

### Example 6

A network-like fine metal particle multilayer film was obtained as described in Example 1, except that the volume of the manifold in the die was 5.0 cc per 10 mm die coating width and that the equivalent cross sectional area of the manifold in the die was 300 mm². The volume of the manifold and the equivalent cross sectional area of the manifold threatened to cause a larger amount of the fine metal particle dispersion to stay in the manifold than those of the die of Example 5.

The obtained network-like fine metal particle multilayer film was like an irregular network. Within the range of the 100 m length, the mean value of the total light transmittance was 79%. The maximum value of the total light transmittance was 81%, and the minimum value was 75%. The variation of the total light transmittance was as good as 4%. However, the mean value of the total light transmittance and the variation of the total light transmittance were inferior to those of Example 1. The mean value of the surface resistivity was 40 Ω/sq. The maximum value of the surface resistivity was 48 Ω/sq., and the minimum value was 35 Ω/sq. The variation of the surface resistivity was as good as 20%. However, the mean value of the surface resistivity was inferior to that of Example 1. The moiré resistance was “A.”

### Example 7

A network-like fine metal particle multilayer film was obtained as described in Example 1, except that the exhaust amount from the exhaust openings of the manifold in the die was 50 vol % with the coating amount supplied from the die as 100 vol %. The exhaust amount was expected to cause a smaller amount of the fine metal particle dispersion to stay in the manifold than that of the die of Example 1.

The obtained network-like fine metal particle multilayer film was like an irregular network. Within the range of the 100 m length, the mean value of the total light transmittance was 80%. The maximum value of the total light transmittance was 82%, and the minimum value was 79%. The dispersion of the total light transmittance was as good as 2%. The maximum value and the minimum value of the total light transmittance were higher than those of Example 1. The mean value of the surface resistivity was 30 Ω/sq. The maximum value of the surface resistivity was 36 Ω/sq., and the minimum value was 27 Ω/sq. The variation of the surface resistivity was as good as 20%. The moiré resistance was “A.”

### Example 8

A network-like fine metal particle multilayer film was obtained as described in Example 1, except that the exhaust amount from the exhaust openings of the manifold in the die was 10 vol % with the coating amount supplied from the die as 100 vol %. The exhaust amount threatened to cause a larger amount of the fine metal particle dispersion to say in the manifold than that of the die of Example 1.

In the obtained network-like fine metal particle multilayer film, within the range of the 100 m length, the mean value of the total light transmission was 79%. The maximum value of the total light transmission was 81%, and the minimum value was 75%. The variation of the total light transmittance was as good as 4%. However, the mean value of the total light transmittance and the variation of the total light transmittance were inferior to those of Example 1. The mean value of the surface resistivity was 40 Ω/sq. The maximum value of the surface resistivity was 48 Ω/sq., and the minimum value was 35 Ω/sq. The variation of the surface resistivity was as good as 20%. The mean value of the surface resistivity was inferior to that of Example 1. The moiré resistance was “A.”

### Example 9

A network-like fine metal particle multilayer film obtained as described in Example 1 was coated with acetone for acetone treatment, to obtain a transparent conductive film.

The obtained transparent conductive film was like an irregular network. Within the range of the 100 m length, the mean value of the total light transmittance was 80%. The maximum value of the total light transmittance was 82%, and the minimum value was 78%. The variation of the total light transmittance was as good as 2%. The mean value of the surface resistivity was 15 Ω/sq. The maximum value of the surface resistivity was 18 Ω/sq., and the minimum value was 12 Ω/sq. The variation of the surface resistivity was 20%. The mean value of the surface resistivity was better than that of Example 1, and the variation of the surface resistivity was also as good as that of Example 1. The moiré resistance was “A.”

### Example 10

A transparent conductive film obtained as described in Example 1 was treated by 1N hydrochloric acid.

The transparent conductive film was like an irregular network. Within the range of the 100 m length, the mean value of the total light transmittance was 80%. The maximum value of the total light transmittance was 82%, and the minimum value was 78%. The variation of the total light transmittance was as good as 2%. Further, the mean value of the surface resistivity was 5 Ω/sq. The maximum value of the surface resistivity was 6 Ω/sq., and the minimum value was 4 Ω/sq. The variation of the surface resistivity was 20%. The mean value of the surface resistivity was better than that of Example 1, and the variation of the surface resistivity was also as good as that of Example 1. The moiré resistance was “A.”

### Comparative Example 1

A network-like fine metal particle multilayer film was obtained as described in Example 1, except that the fine metal particle dispersion 1 was coated using an applicator method.

The obtained network-like fine metal particle multilayer film was like an irregular network. Within the range of the 2 m length, the mean value of the surface resistivity was 50 Ω/sq. The maximum value of the surface resistivity was 65 Ω/sq., and the minimum value was 45 Ω/sq. The variation of the surface resistivity was as good as 30%. The moiré resistance was “A.”

However, concentration unevenness occurred due to the concentration variation of the fine metal particle dispersion in the liquid reservoir when the applicator was used for coating, and the applied coating layer of the network-like fine metal particle multilayer film became uneven. For this reason, though the mean value of the total light transmittance was 76%, the maximum value of the total light transmittance was 78% while the minimum value was 70%. The variation of the total light transmittance was as large as 6%.

### Comparative Example 2

A network-like fine metal particle multilayer film was obtained as described in Example 1, except that the fine metal particle dispersion 1 was coated using a comma coating method.

The obtained network-like fine metal particle multilayer film was like an irregular network. Within the range of the 2 m length, the mean value of the surface resistivity was 50 Ω/sq. The maximum value of the surface resistivity was 65 Ω/sq., and the minimum value was 45 Ω/sq. The variation of the surface resistivity was as good as 30%. The moiré resistance was “A.”

However, concentration unevenness occurred due to the concentration variation of the fine metal particle dispersion in the liquid pan during comma coating, and the applied coating layer of the network-like fine metal particle multilayer film became uneven. For this reason, though the mean value of the total light transmittance was 75%, the maximum value of the total light transmittance was 81% while the minimum value was 67%. The variation of the total light transmittance was as large as 8%. Further, though the mean value of the total light transmittance was more than 70%, the minimum value was smaller than 70%, and a problem in view of transparency occurred partially.

### Comparative Example 3

A lattice with a line thickness of 3 μm and a line width of 50 μm at a pitch of 300 μm was printed by screen printing using the fine metal particle dispersion 2 on one surface of a biaxially oriented polyethylene terephthalate film (“Lumirror” U94 produced by Toray Industries, Inc.). The printed fine metal particle forming solution 2 was dried at 120° C. for 1 minute, to obtain a multilayer film having a fine silver particle layer laminated as a regular lattice-like network thereon.

To treat the fine silver particle layer of the multilayer film by an acid, the multilayer film was immersed in 0.1N (0.1 mol/L) hydrochloric acid (N/10 hydrochloric acid produced by Nacalai Tesque) for 2 minutes. Then, the multilayer film was taken out and washed with water, and subsequently dried at 120° C. for 1 minute, to remove water, for obtaining a meshed conductive film.

The mean value of the surface resistivity of the conductive film was 8 Ω/sq., and the mean value of the total light transmittance was 70%. The maximum value of the total light transmittance was 72%, and the minimum value was 68%. The variation of the total light transmittance was as good as 2%. The maximum value of the surface resistivity was 10 Ω/sq., and the minimum value was 7 Ω/sq. The variation of the surface resistivity was as good as 25%. However, since screen printing was used, only a conductive film of 20 cm×20 cm square could be obtained. Further, as a result of evaluation of moiré, moiré phenomenon occurred.

Production conditions of the respective Examples and Comparative Examples are shown in Table 1, and evaluation results are shown in Table 2.

TABLE 1

| | Fine metal | Volume of manifold | Equivalent cross | Exhaust amount from |
|---|---|---|---|---|
| | particle dispersion | per 10 mm die | sectional area of | the exhaust openings |
| | coating method | coating width (cc) | manifold in die (mm²) | of manifold (vol %) (*1) |
| Example 1 | Die coating method | 0.2 | 13 | 24 |
| Example 2 | Die coating method | 0.2 | 13 | 24 |
| Example 3 | Die coating method | 0.2 | 13 | 24 |
| Example 4 | Die coating method | 0.5 | 30 | 24 |
| Example 5 | Die coating method | 1.0 | 60 | 24 |
| Example 6 | Die coating method | 5.0 | 300 | 24 |
| Example 7 | Die coating method | 0.2 | 13 | 50 |
| Example 8 | Die coating method | 0.2 | 13 | 10 |
| Example 9 | Die coating method | 0.2 | 13 | 24 |
| Example 10 | Die coating method | 0.2 | 13 | 24 |
| Comparative | Applicator method | — | — | — |
| Example 1 | | | | |
| Comparative | Comma coating | — | — | — |
| Example 2 | method | | | |
| Comparative | Screen printing | — | — | — |
| Example 3 | | | | |

(*1) Exhaust amount (vol %) with the coating amount supplied from the delivery openings of the manifold to the film substrate as 100 vol %

TABLE 2

| | Properties of network-like fine metal particle multilayer films (transparent conductive films) | | | | | | | | | | |
|---|---|---|---|---|---|---|---|---|---|---|---|
| | | | Total light transmittance(%) | | | | Surface resistivity | | | | |
| | Network- | Film | Mean | Maximum | Minimum | Varia- | Mean value | Maximum value | Minimum value | Varia- | |
| | like form | length (m) | value | value | value | tion | (Ω/sq.) | (Ω/sq.) | (Ω/sq.) | tion (%) | Moiré |
| Example 1 | Irregular | 100 | 80 | 81 | 78 | 2 | 30 | 36 | 27 | 20 | A |
| Example 2 | Irregular | 2 | 80 | 81 | 79 | 1 | 30 | 33 | 27 | 10 | A |
| Example 3 | Irregular | 2000 | 80 | 81 | 78 | 2 | 30 | 36 | 27 | 20 | A |
| Example 4 | Irregular | 100 | 79 | 81 | 77 | 2 | 30 | 36 | 27 | 20 | A |
| Example 5 | Irregular | 100 | 79 | 81 | 76 | 3 | 30 | 37 | 27 | 23 | A |
| Example 6 | Irregular | 100 | 79 | 81 | 75 | 4 | 40 | 48 | 35 | 20 | A |
| Example 7 | Irregular | 100 | 80 | 82 | 79 | 2 | 30 | 36 | 27 | 20 | A |
| Example 8 | Irregular | 100 | 79 | 81 | 75 | 4 | 40 | 48 | 35 | 20 | A |
| Example 9 | Irregular | 100 | 80 | 82 | 78 | 2 | 15 | 18 | 12 | 20 | A |
| Example 10 | Irregular | 100 | 80 | 82 | 78 | 2 | 5 | 6 | 4 | 20 | A |
| Comparative | Irregular | 2 | 76 | 78 | 70 | 6 | 50 | 65 | 45 | 30 | A |
| Example 1 | | | | | | | | | | | |
| Comparative | Irregular | 2 | 75 | 81 | 67 | 8 | 50 | 65 | 45 | 30 | A |
| Example 2 | | | | | | | | | | | |
| Comparative | Lattice- | 0.2 | 70 | 72 | 68 | 2 | 8 | 10 | 7 | 25 | B |
| Example 3 | like | | | | | | | | | | |

### INDUSTRIAL APPLICABILITY

The network-like fine metal particle multilayer film is highly transparent, unlikely to cause moiré, and small in total light transmittance variation. The network-like fine metal particle multilayer film can be used suitably, for example, for flat panel displays such as plasma display panels and liquid crystal television sets. Further, it can be suitably used for circuit materials, transparent heaters, solar cells and various transparent conductive films.

1. A network-like fine metal particle multilayer film comprising a network-like fine metal particle layer at least on one surface of a film substrate, which has an average total light transmittance of 70% or more, a total light transmittance variation of 5% or less, and a length of 2 m or more.

2. A method for producing the network-like fine metal particle multilayer film of claim 1, comprising coating at least one surface of a film substrate with a fine metal particle dispersion such that a fine metal particle layer network is laminated on the film substrate by die coating.

3. The method according to claim 2, wherein volume of a manifold in a die used for the die coating is 0.01 cc to 5.0 cc per 10 mm die coating width.

4. The method according to claim 2, wherein an equivalent cross sectional area of the manifold in the die is 0.45 mm² to 150 mm².

5. The method according to claim 2, wherein 10 vol % or more of the fine metal particle dispersion is exhausted from the manifold to other than a surface of the film substrate, with a coating amount of the fine metal particle dispersion supplied from the manifold in the die onto the film substrate surface as 100 vol %.

6. The method according to claim 2, wherein air on a surface of the film flows at an air velocity of 1 m/sec to 10 m/sec in a direction within a range of 0±45 degrees with a direction parallel to the film surface as 0 degrees, after coating the film substrate surface with the fine metal particle dispersion.

7. The method according to claim 6, wherein the air flows by air exhausting.

8. An electromagnetic shielding film for a plasma display, obtained from the network-like fine metal particle multilayer film of claim 1.

9. A method for producing a network-like fine metal particle multilayer film comprising coating at least one surface of a film substrate with a fine metal particle dispersion such that a fine metal particle layer network is laminated on the film substrate by die coating with a die containing a manifold with a volume of 0.01 cc to 5.0 cc per 10 mm die coating width.

10. An electromagnetic shielding film for a plasma display, the network-like fine metal particle multilayer film obtained by the network-like fine metal particle multilayer film production method as set forth in claim 2.

11. The method according to claim 3, wherein an equivalent cross sectional area of the manifold in the die is 0.45 mm² to 150 mm².

12. The method according to claim 3, wherein 10 vol % or more of the fine metal particle dispersion is exhausted from the manifold to other than a surface of the film substrate, with a coating amount of the fine metal particle dispersion supplied from the manifold in the die onto the film substrate surface as 100 vol %.

13. The method according to claim 4, wherein 10 vol % or more of the fine metal particle dispersion is exhausted from the manifold to other than a surface of the film substrate, with a coating amount of the fine metal particle dispersion supplied from the manifold in the die onto the film substrate surface as 100 vol %.

14. The method according to claim 3, wherein air on a surface of the film flows at an air velocity of 1 m/sec to 10 m/sec in a direction within a range of 0±45 degrees with a direction parallel to the film surface as 0 degrees, after coating the film substrate surface with the fine metal particle dispersion.

15. The method according to claim 4, wherein air on a surface of the film flows at an air velocity of 1 m/sec to 10 m/sec in a direction within a range of 0±45 degrees with a direction parallel to the film surface as 0 degrees, after coating the film substrate surface with the fine metal particle dispersion.

16. The method according to claim 5, wherein air on a surface of the film flows at an air velocity of 1 m/sec to 10 m/sec in a direction within a range of 0±45 degrees with a direction parallel to the film surface as 0 degrees, after coating the film substrate surface with the fine metal particle dispersion.

17. An electromagnetic shielding film for a plasma display, the network-like fine metal particle multilayer film obtained by the network-like fine metal particle multilayer film production method as set forth in claim 3.

18. An electromagnetic shielding film for a plasma display, the network-like fine metal particle multilayer film obtained by the network-like fine metal particle multilayer film production method as set forth in claim 4.

19. An electromagnetic shielding film for a plasma display, the network-like fine metal particle multilayer film obtained by the network-like fine metal particle multilayer film production method as set forth in claim 5.

20. An electromagnetic shielding film for a plasma display, the network-like fine metal particle multilayer film obtained by the network-like fine metal particle multilayer film production method as set forth in claim 6.
